(19) United States
(12) Patent Application Publication
(10) Pub. No.: US 2020/0252133 A1
(43) Pub. Date: Aug. 6, 2020

(54) PHOTONIC TRANSMITTER WITH OPTICAL AMPLIFIER

(71) Applicant: Intel Corporation, Santa Clara, CA (US)

(72) Inventors: Jin Hong, Saratoga, CA (US); Wenhua Lin, Fremont, CA (US)

(73) Assignee: Intel Corporation, Santa Clara, CA (US)

(21) Appl. No.: 16/854,450

(22) Filed: Apr. 21, 2020

(51) Int. Cl. H04B 10/564; H04B 10/50; H04B 10/25; H01S 5/343; H01S 5/34; H01S 5/50

(52) U.S. Cl. CPC H04B 10/564; H04B 10/505; H01S 5/50; H01S 5/343; H01S 5/3412; H04B 10/25

(57) ABSTRACT

Embodiments may relate to an optical transmitter that includes a laser to produce an optical signal, and a modulator to encode data into the optical signal to produce an optical data signal. The optical transmitter may further include an amplifier that is to amplify a power of the optical data signal to produce an output signal. Other embodiments may be described or claimed.

### BACKGROUND

One challenge in silicon photonics high-power optical devices (e.g., hybrid lasers) is how to avoid or eliminate the catastrophic optical damage (COD) which may be caused by the combination of high injection current and high optical power inside the laser cavity and between the III-V material and silicon of the optical device. In general, COD may be related to or based on the optical power density inside the optical waveguide, and the risk of COD may increase as optical power of the transmitter increases. Another challenge may be that increasing optical power may be desired in the more complicated integrated silicon photonics devices due to various factors.

### BRIEF DESCRIPTION OF THE DRAWINGS

FIG. 1 depicts an example optical transmitter, in accordance with various embodiments.

FIG. 2 depicts an alternative example optical transmitter, in accordance with various embodiments.

FIG. 3 depicts an alternative example optical transmitter, in accordance with various embodiments.

FIG. 4 depicts an alternative example optical transmitter, in accordance with various embodiments.

FIG. 5 depicts an alternative example optical transmitter, in accordance with various embodiments.

FIG. 6 depicts an alternative example optical transmitter, in accordance with various embodiments.

FIG. 7 depicts an alternative example optical transmitter, in accordance with various embodiments.

FIG. 8 depicts an alternative example optical transmitter, in accordance with various embodiments.

FIG. 9 is a block diagram of an example electrical device that may include an optical transmitter with an amplifier, in accordance with various embodiments.

FIG. 10 depicts an example system in which a plurality of optical components may be used, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

Various operations may be described as multiple discrete operations in turn, in a manner that is most helpful in understanding the claimed subject matter. However, the order of description should not be construed as to imply that these operations are necessarily order dependent.

As previously noted, COD may be detrimental to high-power optical devices such as hybrid lasers. COD may be sensitive to the optical power density inside the optical waveguide, and the risk of COD may increase significantly with the increase of optical power. Therefore, COD may limit or prevent the commercialization or applications of high-powered silicon photonics devices.

Another challenge may be that increasing optical power may be desired in the more complicated integrated silicon photonics devices due to various factors. The factors may include the extra optical loss caused by device integrations. Another factor may be the increasing need for higher and higher order of modulations to support high-capacity interconnects. For example, it may be desirable to use advanced modulations like pulse amplitude modulation (PAM)-x for non-coherent applications or quadrature amplitude modulation (QAM)-x for coherent applications where x can be 4, 8, 16, 64, or higher. In these embodiments, modulation-related optical losses may increase with increasing modulation-order.

When the high-power lasers and the high-power amplification gain mediums are monolithically integrated together through the hybrid wafer bonding process, these above-described challenges may increase the difficulty or reliability of such monolithic integration. How to distributed optical power along the transmitter and receiver chain, while avoiding the very high optical intensity in any particular portion of the device to mitigate the risk of COD, is increasing in importance for various emergent silicon photonics applications.

Generally, silicon photonics transmitters that incorporate hybrid integrated lasers may be desired to meet the link budget in signal power-limited optical systems. Such hybrid integrated lasers may include III-V material that is bonded on a silicon substrate. In a legacy optical system without any in-line distributed semiconductor gain medium, the optical power emitted from the silicon photonics transmitter may meet the required minimum signal optical power for binary non-return to zero (NRZ) modulation at the receiver. The minimum signal optical power may be based on, for example, the receiver sensitivity for the optical system to have a bit error rate (BER) that is lower than a specified value.

However, PAM-4 signaling may be used in legacy optical transceivers, enabling net data transmission rates on the order of up to 100 gigabits per second (Gb/s) per lane. Compared to traditional binary NRZ modulation, PAM-4 modulation may double the data rate in a 4-level time-domain signal, and may also require higher transmitter optical power. For example, the transmitter may need to increase the laser power by 4 decibels with reference to one milliwatt (dBm) from 10 dBm in the case of NRZ modulation to 14 dBm in the case of PAM-4 modulation in order to meet tighter sensitivity at the receiver. For example, in some cases the stressed receiver sensitivity may be tightened by approximately 3.7 decibels (dB) from −6.3 dBm for NRZ modulation to −2.6 dBm for PAM-4 modulation.

Legacy solutions to meeting these power requirements may be to increase the output optical power of the laser. The optical power may be increased by, for example, lengthening the laser cavity and thereby reducing the photonic density along the laser cavity. The increased laser output optical power may additionally be achieved by improving the laser cavity design and laser fabrication processes, especially the III-V material bonding to silicon wafers for a high optical output power laser. However, this approach may produce a laser reliability risk caused by COD due to the increased optical power density inside the laser cavity.

One example use case of such an optical transceiver may be a wavelength-division multiplexing (WDM) optical system which is deployed for data center interconnect, metro, and long-haul transport systems. The WDM system may combine multiple laser wavelength channels into a single optical fiber, for example by using a wavelength-division multiplexer. As the channel count (which may be between 1 and 32 wavelength channels, or more) and the data rate (e.g., 100 Gb/s for PAM-4 modulation and on the order of 600 GB/s for coherent QAM-64 modulation) increases, the demand of the higher optical power link may be desired. Legacy solutions may face the challenge of increased nonlinear effects, which may be induced by higher power intensity inside the small core silicon waveguide with a high refractive-index contrast. Because of the relatively small effective core area (which may be, for example based on a waveguide dimension of approximately 400 nanometers (nm) by approximately 200 nm), the optical power density of the silicon waveguide may be on the order of 200-1000 times higher than that of a conventional single-mode fiber for nonlinearity limits such as four-wave mixing (FWM) or two-photon absorption (TPA).

To resolve the above-described challenges, embodiments herein relate to a silicon photonics-based optical transmitter architecture that includes distributed gain mediums along the transmitter chain, provides larger and more configurable optical link budget suitable for high-speed/high channel count, and longer distance data center interconnect applications with speeds on the order of 100 Gb/s to multiple terabits per second. Embodiments may use less output optical power from silicon photonics-based hybrid lasers, without the need for high-power lasers, and therefore mitigate or avoid the possibility of COD which may occur inside the optical cavity of high-power lasers. Embodiments may also distribute the optical gain medium, and therefore the optical power, along the device chain to reduce, minimize, or eliminate the higher-power inducted nonlinear effects inside the silicon photonics chips. Therefore, embodiments herein may allow the commercialization of silicon photonics devices for various applications.

Specifically, embodiments may relate to a transmitter architecture design. In the architecture design, the higher optical power and the resulting configurable optical link budget may be distributed into separate parts of the transmitter train. The first part may be the hybrid laser that includes a III-V gain material and silicon photonics-based laser. The laser may be designed with relatively low optical power, which may reduce or eliminate the risk of COD in the optical transmitter.

The second part may be a separate and hybrid integrated gain section that also includes III-V gain material on a silicon photonics-based platform. The III-V based gain section which may amplify the PAM-4 optical signal subsequent to modulation by, for example, a high-speed silicon photonics modulator. The gain section may be placed on multiple of the parallel optical paths, or on the single output optical path after an optical multiplexer which is used to combine the parallel optical paths into a single path. The length and shape of the III-V based gain medium may be designed to accommodate various applications with different link budget requirements. The optical link budget may be configured by the adjustment of the electrical injection current into hybrid lasers and various gain mediums, and the manufacturing yield may also be increased by the adjustment of the gain medium currents. A tapered gain medium or a curved gain medium may also be used in the amplifier to simply the link budget configuration.

A third part may be the addition of multiple gain mediums to further distribute and configure the optical power link budget. This distribution may lead to the mitigation of laser power, and therefore the reduction or elimination of power-dependent nonlinear effects inside the silicon photonics chips.

Embodiments herein may include a number of advantages over legacy optical solutions. For example, with the hybrid III-V gain medium implemented after the modulator, the optical power inside the III-V gain medium may be relatively low due to the optical loss of modulators. This relatively low optical power may reduce or eliminate the risk of COD inside the III-V gain medium. In such an arrangement, both the laser and the gain medium may not be operating at a very high optical power mode, and therefore both the COD risk and power-dependent nonlinear risks may be significantly reduced. The total output power may still be high enough for the stated applications to meet an identified optical link budget for the optical transmitter. This distribution of several gain mediums along the transmitter train may enable new product design options with higher output optical power, configurable link budget, extended optical transmission reach, and excellent reliability.

Embodiments may also allow for the creation and production of multiple new high-speed and high-capacity products to meet requirements by hyper scale cloud service providers. For example, embodiments may include 400 Gb/s transceivers, 800 Gb/s transceivers, 1.6 terabytes per second (Tb/s) or 3.2 Tb/s optical transceivers or on-board optics (OBO), all of which may be with or without some levels of integrated optical multiplexer or demultiplexer.

Finally, these new architecture configurations may allow for a relatively high link budget. The high link budget may compensate for any dispersion penalty of the optical transmitter or electronic device of which the optical transmitter is a part. Therefore, embodiments may enable the transmission of high-speed optical signals over increasing distances or wider wavelength spectrums.

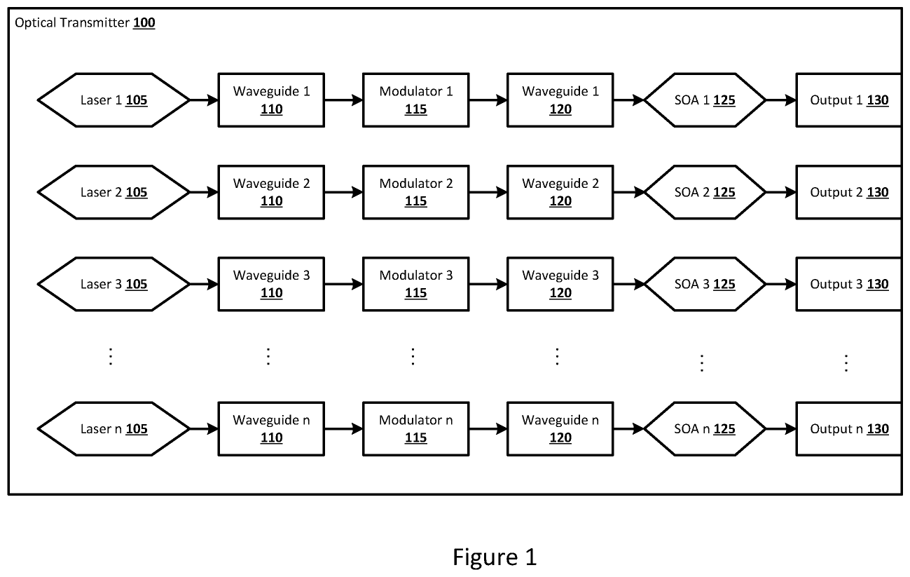

FIGS. 1-8 and 10 depict various examples of systems or optical transmitters, in accordance with embodiments herein. The specific size, spacing, or number of elements in the various Figures is intended to depict various examples of embodiments herein but should not be viewed as limiting unless explicitly stated to the contrary. For example, certain elements may be larger or smaller than depicted. Additionally, there may be additional elements than are depicted. For example, various of the optical transmitters may include more or fewer optical paths than are depicted, etc. Other variations may be present in other embodiments.

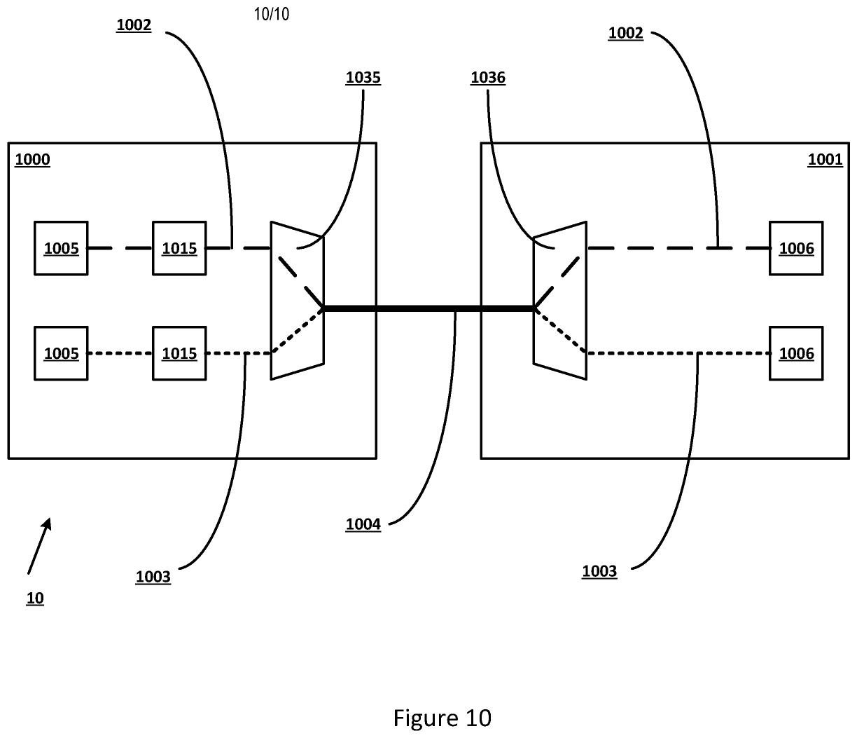

FIG. 10 depicts an example system 10 in which a plurality of optical components may be used, in accordance with various embodiments. Specifically, as shown in FIG. 10, the system 10 may include a transmitter 1000 and a receiver 1001. It will be understood that although the system 10 is shown with a transmitter 1000 and a receiver 1001, in some embodiments element 1000 or element 1001 may be a transceiver. That is, element 1000 or element 1001 may include both of a transmit path and a receive path. However, only the transmit path of element 1000 and only the receive path of element 1001 are depicted for the sake of easy of discussion and illustration of concepts related to embodiments herein. It will also be understood that FIG. 10 is a highly simplified Figure and the elements 1000 or 1001 may include additional elements as may be described in other Figures.

The system 10 may include a plurality of optical paths 1002 and 1003. Using optical path 1002 as an example, the transmitter 1000 may include a laser 1005 which may generate light. The light generated by the laser 1005 may propagate along the optical path 1002 to a modulator 1015. The modulator 1015 may be coupled with a data source (not shown) which may provide a data signal to the modulator 1015. The data source may be, for example, a processor, a processor core, or some other data source of an electronic device which may provide a data signal. The modulator 1015 may modulate the light generated by the laser 1005 to encode the data from the data signal into the light to form a modulated optical signal.

The modulated optical signal from the modulator 1015 may then be provided to a multiplexer (MUX) 1035 which may be, for example a wavelength-division MUX. The MUX 1035 may combine the modulated optical signals from optical paths 1002 and 1003 into a single optical signal which may be output from the transmitter 1000 as a multiplexed optical signal 1004. For example, the transmitter 1000 may be communicatively coupled with an optical fiber such as a single-mode fiber (SMF), an optical waveguide, or some other structure that is configured to convey an optical signal between the transmitter 1000 and the receiver 1001.

The receiver 1001 may include a demultiplexer (DEMUX) 1036. The DEMUX 1036 may receive the multiplexed optical signal 1004 and separate the multiplexed optical signal into the separate modulated optical signals of optical paths 1002 and 1003. The modulated optical signals may then be provided to receiver circuitry 1006 which may be configured to process the modulated optical signals to, for example, extract the data signal that was modulated into the optical signal by the modulators 1015.

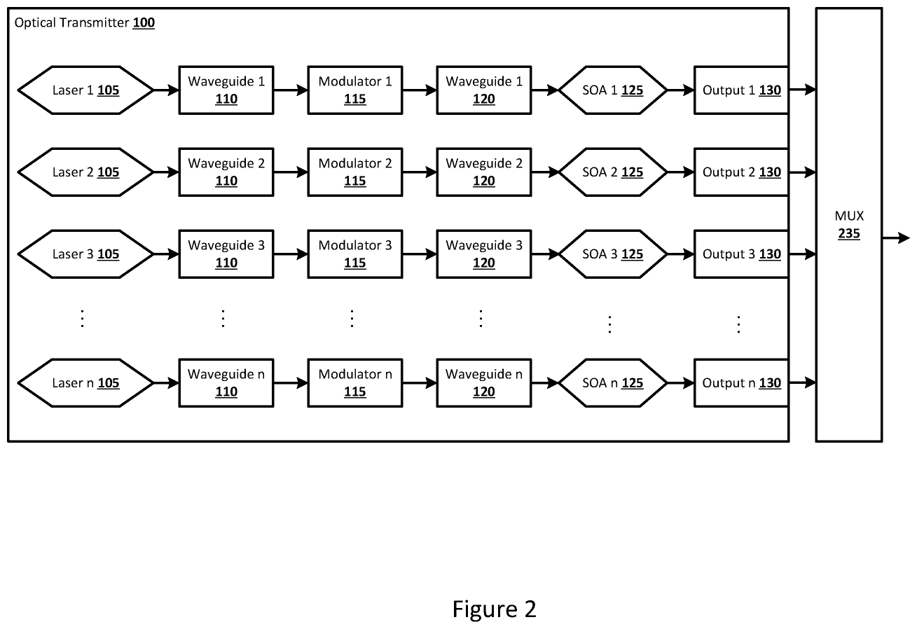

FIGS. 1-8 depict various optical transmitters which may be similar to, for example, optical transmitter 1000. Specifically, FIG. 1 depicts an example optical transmitter 100. As may be seen, the optical transmitter 100 may include n optical paths. For example, a first optical path may include elements with the indicator “1;” another optical path may include elements with the indicator “2;” etc. This numbering scheme may also be applicable to other embodiments such as those described in FIGS. 2-8. It will be understood that although four optical paths are depicted in FIG. 1, in other embodiments there may be fewer or more. For example, in some embodiments n may be on the order of 32 or higher dependent on the desired bandwidth or capabilities of the optical transmitter.

Respective ones of the optical paths may include a laser 105. As previously noted with respect to laser 1005, the laser may be configured to generate light and output the generated light to a waveguide 110. In some embodiments, the laser may include a III-V material that is deposited on a silicon substrate (e.g., a substrate of the optical transmitter). In some embodiments, the III-V material may include a quantum dot (QD) gain material or a quantum well (QW) gain material. Specifically, in these embodiments the III-V material may include a gain material such as a QW material or a QD material.

Generally, a QW material (which may also be referred to as a multiple quantum well (MQW) material) may refer to a III-V material that includes an indium aluminum gallium arsenide (InAlGaAs) epitaxial layer gain material on indium phosphide (InP). Specifically, the InAlGaAs material may be epitaxially grown on one or more layers of InP. The QW material may, for example, include three layers of InAlGaAs wells in layers with a thickness of approximately 7 nm; and four layers of InAlGaAs barriers with a thickness of between approximately 9 nm and approximately 60 nm. The wells and barriers may alternate in the QW structure. In other embodiments, a QW material may be, for example, five layers of InAlGaAs wells and six layers of InAlGaAs barriers, wherein the wells and barriers alternate.

A QD material may relate to gallium arsenide (GaAs) and indium gallium arsenide (InGaAs) based QD gain material. More specifically, the gain region may, in some embodiments, include five repeating layers of InGaAs dot layers embedded within InGaAs well regions. The InGaAs may be separated with GaAs layers.

Generally, there may be multiple choices for gain medium design. For example, in some embodiments the gain medium may employ QW-based structures. However, in other embodiments, the QD gain medium structure may provide additional benefits due to its insensitivity to external optical feedback, its low threshold, and its high available gain, so that the total optical power required may be less or comparable with that from a high-power laser.

QD gain material may, in some embodiments, be preferable to QW gain material due to the increased carrier confinement created by the 3D confinement of the charge carriers and the resulting improvement of the density of states. As an example, the III-V material may be designed and epitaxially grown to create a combination of QW and QD gain layers. The isolation and confinement regions in QD may form an efficient bandgap structure, improve carrier confinement, and hence improve gain material efficiency afforded by this gain region design. The III-V material may then be bonded to the silicon wafer surface above the silicon rib waveguide.

As can be seen, the optical transmitter 100 may include a number of lasers 105 in a number of optical paths. One or more of the lasers 105 may output light with a different frequency than another of the lasers 105. In other embodiments, one or more of the lasers 105 may output light a same frequency as another of the lasers 105.

The laser 105 may output light to a waveguide 110 which may be, for example, a silicon rib waveguide, a planar waveguide, or some other type of waveguide. The waveguide 110 may allow the light output from the laser 105 to propagate to a modulator 115, which may be similar to the modulators 1015 described above.

As previously noted, respective ones of the modulators 115 may be communicatively coupled with a data source that is configured to produce a data signal. The data source may be, for example, a processor, a processor core, or some other type of logic. The modulator may be configured to encode the data into the light output by the laser 105 and received from the waveguide 110. The modulator may be, for example, a high-speed silicon photonics modulator that is operable to modulate the light using PAM modulation, QAM modulation, or some other type of modulation.

The modulator 115 may then output the modulated optical signal along a waveguide 120 to a semiconductor optical amplifier (SOA) 125. The waveguide 120 may be similar to, for example, waveguide 110.

The SOA 125 may share one or more characteristics of the laser 105 as described above. Specifically, the SOA 125 may include a III-V gain material such as a QD gain material or a QW gain material as described above with respect to the laser 105. In some embodiments, the laser (e.g., laser 105) and the SOA (e.g. SOA 125) may be fabricated at the same time, and therefore include III-V materials with properties that are substantially identical to one another. Generally, the SOA 125 may be to amplify the modulated optical signal that is output from the modulator 115 (and received through the waveguide 120). The amplified modulated optical signal may then be introduced to an output 130 of the optical transmitter 100, which may be configured to output the signal.

As may be seen in the example optical transmitter of FIG. 1, the SOAs 125 may include a taper at both the input and the output of the SOA 125. The taper at the input of the SOA 125 and the taper at the output of the SOA 125 may be desirable, because they may allow from an adiabatic transition of the optical signal between the SOA 125 and the waveguide 120 or the output 130.

In this way, the optical transmitter 100, and particularly the SOAs 125 may enable solutions to one or more of the challenges described above. Specifically, as noted, it may be desirable for the optical transmitter 100 to have a relatively high power output. However, in legacy solutions the power output may have required a laser with a very high power output, which may have increased the likelihood of COD occurring inside of the optical transmitter. This likelihood may have been in part because the power of the optical signal may be reduced as it traverses through the modulator 115 (e.g., by y) Therefore, in order to have the optical transmitter 100 output a signal with a sufficient power level (e.g., x), it may have been required for the laser 105 to output an initial signal with a power level of x+y.

However, due to the presence of the SOA 125, the signal output by the modulator 115 may be boosted, and so it may not be required for the laser 105 to have the same high output power. Therefore, the COD of the optical transmitter may be reduced or eliminated. As one example, the laser 105 may output an optical signal with a power between approximately 10 and approximately 40 milliwatts (mW). The optical signal of the laser 105 may be reduced as it traverses the optical path and, particularly, by the modulator 115. However, the SOA 125 may amplify the modulated optical signal so that the signal output by output 130 has a power of at least 5 dBm. In some embodiments, the SOA 125 may be configured to amplify the modulated optical signal so that the signal output by output 130 has a power of at least 10 dBm. Specifically, in some embodiments the SOA 125 may amplify the power of the modulated optical signal by at least 4 dB. More generally, the SOA 125 may amplify the power of the modulated optical signal by between approximately 3 dB and approximately 10 dB. It will be understood, however, that these values are intended as examples of one embodiment, and the values of the amplification, the output signal produced by the optical transmitter 100, or the power of the optical signal produced by the laser 105 may be different in different embodiments based on factors such as specific use cases, materials used, design tolerances, etc.

FIG. 2 depicts an alternative example optical transmitter, in accordance with various embodiments. Specifically, in this embodiment the optical transmitter 100 may be communicatively coupled with a MUX 235. The MUX 235 may be similar to, for example, MUX 1035 of FIG. 10. Specifically, the MUX 235 may be configured to receive the signals from the various outputs 130 of the optical transmitter 100 and combine the signals into a multiplexed optical signal which may be similar to, for example, multiplexed optical signal 1004 of FIG. 10. In various embodiments, the MUX 235 may perform this function based on the use of active circuitry, passive circuitry, a specific physical structure, or some other means.

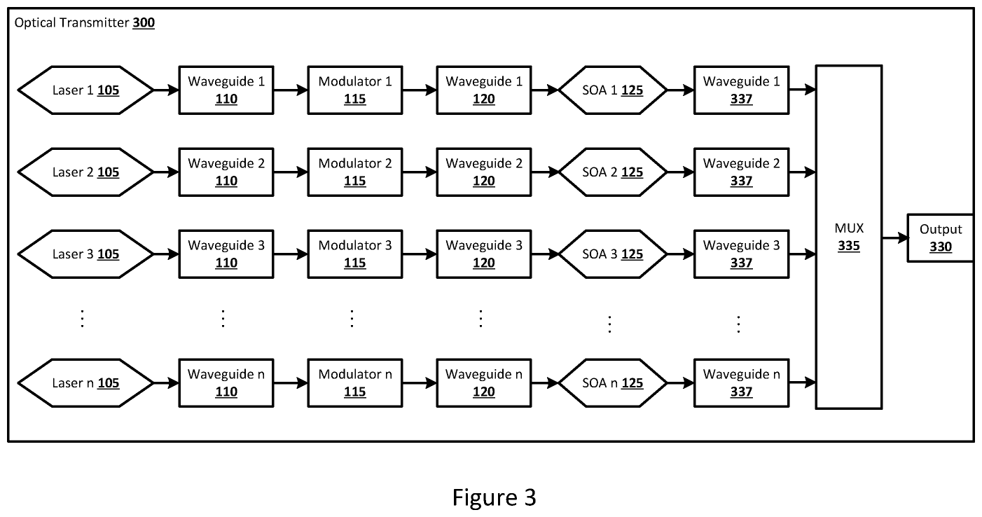

FIG. 3 depicts an alternative example optical transmitter 300, in accordance with various embodiments. The optical transmitter 300 may be similar to, and share one or more characteristics with, optical transmitter 100. However, in this embodiment the MUX 335 (which may be similar to MUX 235) may be an element of the optical transmitter 300. Respective ones of the optical paths may include a waveguide 337 to facilitate transmission of the amplified optical signal from the SOA 125 to the MUX 335. The waveguide 337 may be similar to, for example, waveguides 110 or 120. The MUX 335 may then output the multiplexed optical signal to output 330 where the signal may be output from the optical transmitter 300, e.g. to an optical fiber that is communicatively coupled with the optical transmitter 300 as described previously.

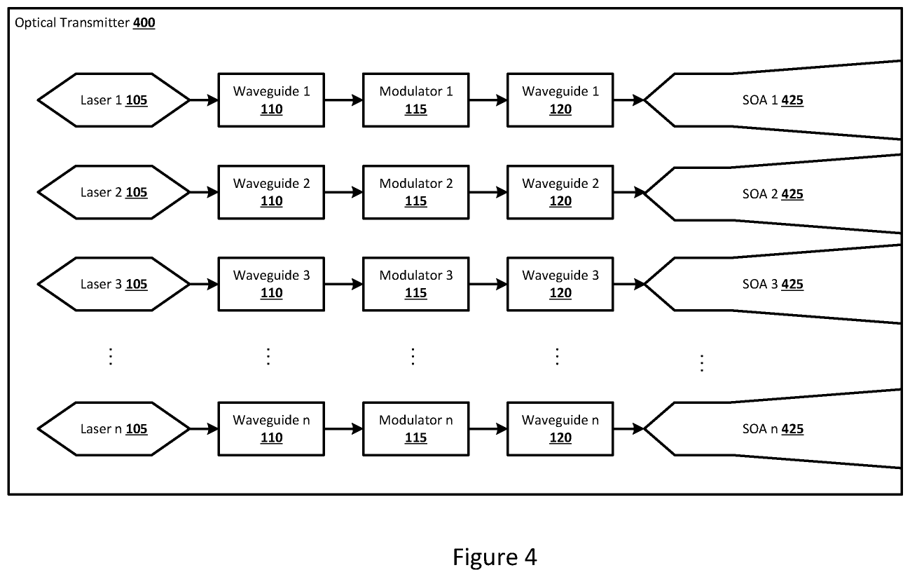

FIG. 4 depicts an alternative example optical transmitter 400, in accordance with various embodiments. The optical transmitter 400 may be similar to, and share one or more characteristics with, optical transmitter 100. However, in this embodiment the optical transmitter 400 may not include outputs such as outputs 130. Rather, as may be seen, the optical transmitter 400 may include a number of SOAs 425 which may be similar to, and share one or more characteristics with, SOAs 125. Specifically, the SOAs 425 may include a III-V gain medium on a silicon substrate as described above with respect to SOAs 125. However, in this embodiment the SOAs 425 may have a tapered profile wherein they expand along the length of the optical pathway. This profile may allow the SOAs 425 to serve as both amplifiers as well as outputs such as outputs 130. Therefore, there may not be a need for extra outputs such as outputs 130. In some embodiments, the tapered profile of the SOA 425 may also help to increase the power of the modulated optical signal before the optical signal is output from the optical transmitter. It will be understood that the degree of taper, the length of the SOA 425, etc. is depicted as an example embodiment; and other embodiments may have different degrees or directions of taper, different relative lengths, or other dimensions. Additionally, in some embodiments, different ones of the SOAs 425 may have different degrees of tapers, or one or more of the SOAs 425 may be tapered while others of the SOAs 425 are not tapered. Other variations may be present in other embodiments.

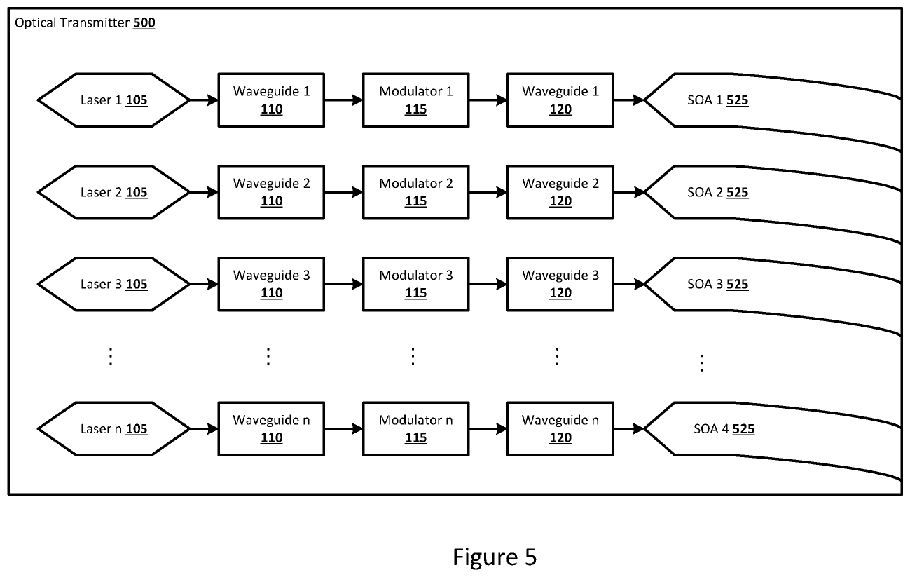

FIG. 5 depicts an alternative example optical transmitter 500, in accordance with various embodiments. The optical transmitter 500 may be similar to, and share one or more characteristics with, optical transmitter 100. However, in this embodiment the optical transmitter 500 may not include outputs such as outputs 130 (similarly to the embodiment of FIG. 4). Rather, as may be seen, the optical transmitter 500 may include a number of SOAs 525 which may be similar to, and share one or more characteristics with, SOAs 125. Specifically, the SOAs 525 may include a III-V gain medium on a silicon substrate as described above with respect to SOAs 125. However, in this embodiment the SOAs 525 may have a curved profile as depicted. The curved profile may be desirable because it may help mitigate, reduce, eliminate, or otherwise affect the possibility of back reflections as the light is output from the optical transmitter 500. Similarly to the discussion above with respect to FIG. 4, it will be understood that the degree of curve, the length of the SOA 525, etc. is depicted as an example embodiment; and other embodiments may have different degrees or directions of curve, different relative lengths, or other dimensions. Additionally, in some embodiments, different ones of the SOAs 525 may have different degrees of curve, or one or more of the SOAs 525 may be curved while others of the SOAs 525 may not be curved. Other variations may be present in other embodiments.

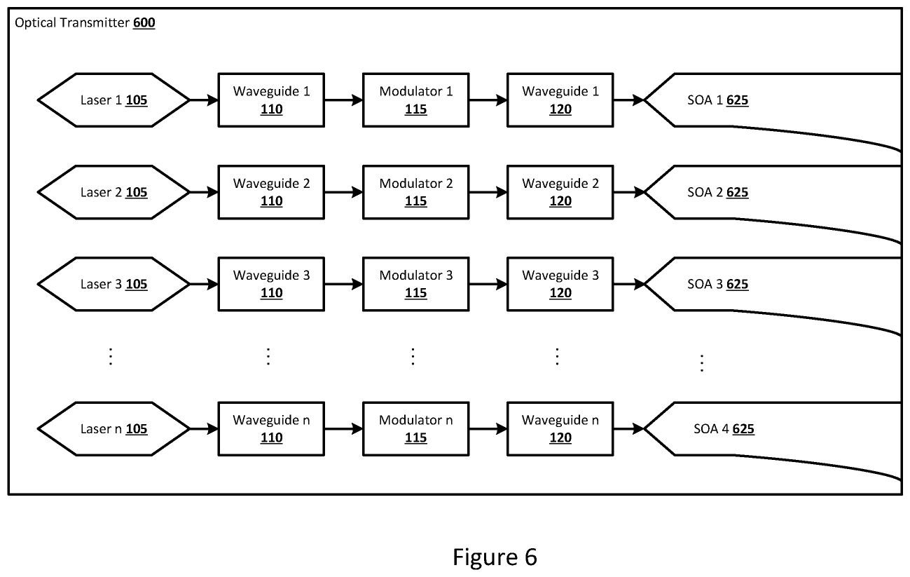

Some embodiments may include aspects or features that are combinations of elements of other embodiments. For example, FIG. 6 depicts an alternative example optical transmitter 600, in accordance with various embodiments. The optical transmitter 600 may be similar to, and share one or more characteristics with, optical transmitter 100. Similarly to the optical transmitters 400 and 500, the optical transmitter 600 may not include a separate output, but rather may use the SOAs 625 to perform both an amplification function and a signal output function. In this embodiment, the SOAs 625 may be tapered (e.g., in a manner similar to the taper of SOAs 425) as well as curved (e.g., in a manner similar to the curve of SOAs 525). Similarly to the variations described with respect to SOAs 425 or 525, the SOAs 625 may vary with respect to the degree of taper, degree of curve, etc. Additionally, as previously noted, although the various SOAs 625 are depicted as being generally identical to one another, in other embodiments various of the SOAs 625 may differ from one another with respect to the degree, type, or even existence of curvature or taper. For example, in some embodiments one SOA may be as shown in FIG. 6, another SOA may be as shown in FIG. 5, another SOA may be as shown in FIG. 4, and another SOA may be as shown in FIG. 1 and include an output such as output 130. Other variations may be present in other embodiments.

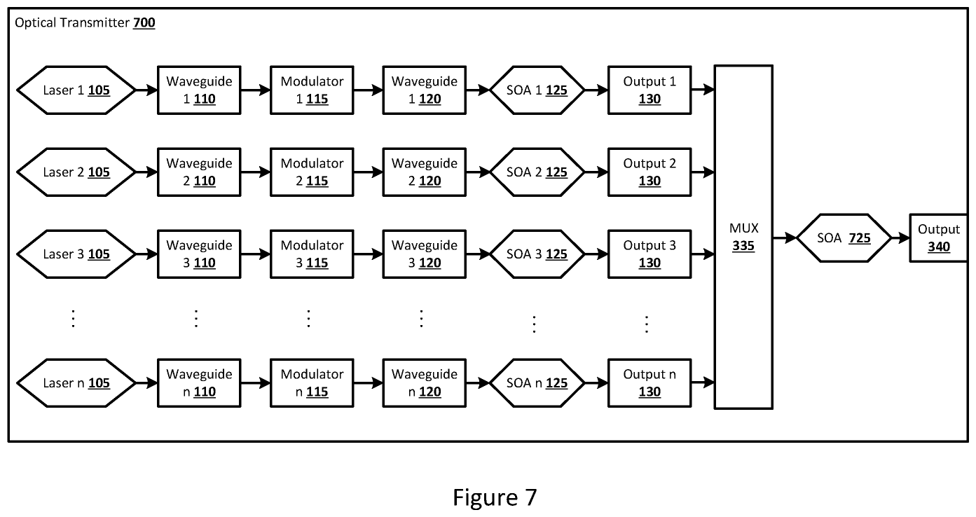

In some embodiments, it may be desirable to put another SOA after the MUX. For example, the MUX may reduce power of the signal, or in some embodiments if the optical signal is boosted too much prior to multiplexing, it may damage the MUX. FIG. 7 depicts an alternative example optical transmitter 700, in accordance with various embodiments. The optical transmitter 700 may be similar to, and include elements that are similar to, those of optical transmitters 100 or 300. In this embodiment, the optical transmitter 700 may include an SOA 725 communicatively located between the MUX 335 and the output 340. The SOA 725 may be similar to, and share one or more characteristics with, SOA 125 or some other SOA described herein. In this embodiment, as previously noted, the SOA 725 may serve to amplify the multiplexed optical signal that is output by the MUX 335. By amplifying the multiplexed optical signal, the chance of the aggregated multi-wavelength optical power within the MUX may be significantly reduced, thus eliminating or minimizing the nonlinear FWM or TPA impairments in the transmitter.

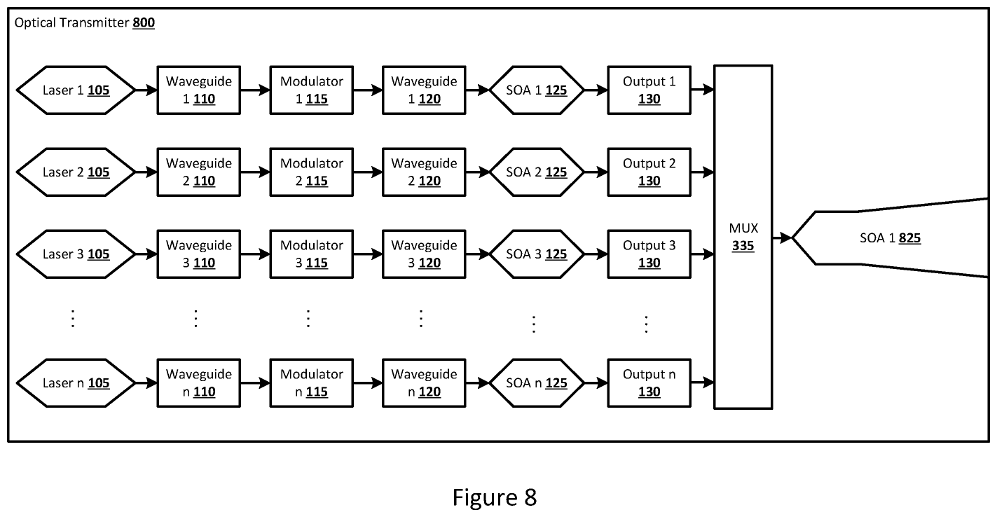

FIG. 8 depicts an alternative example optical transmitter 800 in accordance with various embodiments. The optical transmitter 800 may be similar to, and include elements that are similar to, those of optical transmitters 100 or 300. It may also be seen that the optical transmitter 800 may be generally similar to optical transmitter 700 in that the optical transmitter 800 may include an SOA 825 in the optical pathway after the MUX 335. However, in this embodiment a separate output such as output 340 may not be necessary because the SOA 825 may be generally similar to SOA 425. That is, as may be seen, the SOA 825 may be tapered in a manner similar to that shown and described with respect to SOA 425. It will be understood, however, that in other embodiments the SOA 825 may additionally or alternatively be curved such as is shown with respect to SOAs 525 or 625. Other variations may be present in other embodiments.

As noted, it will be understood that the embodiments of FIG. 1-8 are intended as examples of various embodiments to discuss or describe various concepts which may be applied to the use of a SOA in an optical transmitter. However, other embodiments may include more or fewer elements than described, elements in a different order in the optical paths, etc. Additionally, other embodiments may include combinations of concepts of various of the Figures. Other variations may be present.

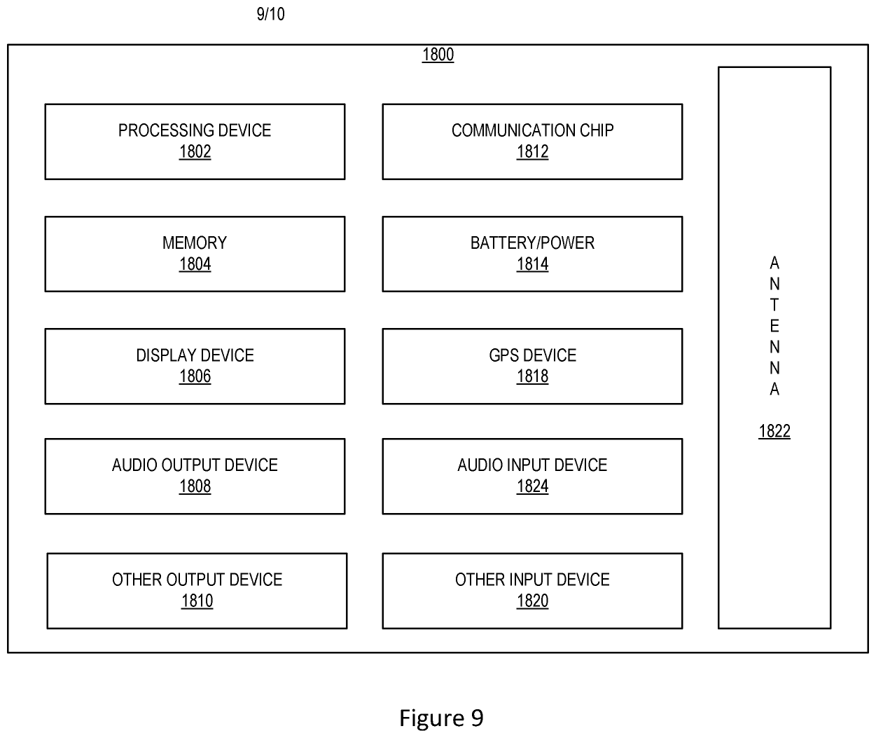

FIG. 9 is a block diagram of an example electrical device 1800 that may include one or more optical transmitter with an amplifier, in accordance with any of the embodiments disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications. In some embodiments, the communication chip 1812 may be or may include an optical transmitter such as optical transmitter 100 or some other optical transmitter discussed herein.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

### Examples of Various Embodiments

Example 1 includes an optical transmitter comprising: a laser to produce an optical signal with a power between 10 and 40 milliwatts (mW); a modulator to encode data into the optical signal to produce an optical data signal; and an amplifier to amplify a power of the optical data signal to produce an output signal with a power of at least 10 decibels with reference to one milliwatt (dBm).

Example 2 includes the optical transmitter of example 1, or some other example herein, wherein the laser or the amplifier include a III-V material on a silicon substrate of the optical transmitter.

Example 3 includes the optical transmitter of example 2, or some other example herein, wherein the III-V material includes a QD structure.

Example 4 includes the optical transmitter of example 3, or some other example herein, wherein the QD structure includes one or more gallium arsenide (GaAs) layers within one or more indium gallium arsenide (InGaAs) wells.

Example 5 includes the optical transmitter of example 2, or some other example herein, wherein the III-V material includes a MQW structure.

Example 6 includes the optical transmitter of example 5, or some other example herein, wherein the MQW structure includes indium aluminum gallium arsenide (InAlGaAs) and indium phosphide (InP).

Example 7 includes the optical transmitter of any of examples 1-6, or some other example herein, wherein the power of the optical data signal is less than the power of the optical signal.

Example 8 includes the optical transmitter of any of examples 1-6, or some other example herein, wherein the amplifier is to amplify the power of the optical data signal by at least 4 decibels (dB).

Example 9 includes an electronic device comprising: an active element to produce a data signal; and an optical transmitter to produce an output signal with a power of at least 5 decibels with reference to one milliwatt (dBm), wherein the optical transmitter includes: a substrate; a laser coupled with the substrate, wherein the laser is to produce an optical signal with a power between 10 and 40 milliwatts (mW); a modulator coupled with the substrate, wherein an input of the modulator is communicatively coupled with an output of the laser, and wherein the modulator is to encode the data signal into the optical signal to produce an optical data signal with a power less than the power of the optical signal; and a semiconductor optical amplifier (SOA) coupled with the substrate, wherein an input of the SOA is communicatively coupled with an output of the modulator, and wherein the SOA is to amplify the power of the optical data signal to produce the output signal, and wherein the SOA includes a III-V material.

Example 10 includes the electronic device of example 9, or some other example herein, or some other example herein, wherein the SOA has a curved profile.

Example 11 includes the electronic device of example 9, or some other example herein, wherein the SOA has a tapered profile.

Example 12 includes the electronic device of any of examples 9-11, or some other example herein, wherein the optical transmitter further includes an optical coupler that is to couple with an optical fiber, wherein the optical coupler is to receive the output signal.

Example 13 includes the electronic device of any of examples 9-11, or some other example herein, wherein the SOA is to directly couple with, and provide the output signal to, an optical fiber.

Example 14 includes the electronic device of any of examples 9-11, or some other example herein, wherein the optical transmitter further includes a multiplexer that is to receive the output signal.

Example 15 includes an optical transmitter comprising: a first optical signal path that includes: a first laser to produce a first optical signal with a power of less than 40 milliwatts (mW); a first amplifier to produce a first output signal with a power of at least 5 decibels with reference to one milliwatt (dBm), wherein the first output signal is based on the first optical signal; a second optical signal path that includes: a second laser to produce a second optical signal with a power of less than 40 mW; a second amplifier to produce a second output signal with a power of at least 5 dBm, wherein the second output signal is based on the second optical signal; and a multiplexer to combine the first output signal and the second output signal to produce a multiplexed output signal.

Example 16 includes the optical transmitter of example 15, or some other example herein, further comprising a third amplifier to increase a power of the multiplexed output signal.

Example 17 includes the optical transmitter of example 16, or some other example herein, further comprising an optical coupler communicatively positioned between the multiplexer and the third amplifier.

Example 18 includes the optical transmitter of example 16, or some other example herein, further comprising an optical coupler communicatively coupled with an output of the third amplifier.

Example 19 includes the optical transmitter of example 16, or some other example herein, wherein the third amplifier has a tapered profile as viewed in a direction perpendicular to a face of a substrate to which the first laser is coupled.

Example 20 includes the optical transmitter of example 16, or some other example herein, wherein the third amplifier has a curved profile as viewed in a direction perpendicular to a face of a substrate to which the first laser is coupled.

Example 21 includes the optical transmitter of any of examples 15-20, or some other example herein, wherein the multiplexer is physically coupled to a same substrate as the first laser and the second laser.

Example 22 includes the optical transmitter of any of examples 15-20, or some other example herein, wherein the multiplexer is physically separate from a substrate to which the first laser is coupled.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. An optical transmitter comprising:
a laser to produce an optical signal with a power between 10 and 40 milliwatts (mW);
a modulator to encode data into the optical signal to produce an optical data signal; and
an amplifier to amplify a power of the optical data signal to produce an output signal with a power of at least 10 decibels with reference to one milliwatt (dBm).

2. The optical transmitter of claim 1, wherein the laser or the amplifier include a III-V material on a silicon substrate of the optical transmitter.

3. The optical transmitter of claim 2, wherein the III-V material includes a quantum dot structure.

4. The optical transmitter of claim 2, wherein the III-V material includes a multiple quantum well (MQW) structure.

5. The optical transmitter of claim 1, wherein the power of the optical data signal is less than the power of the optical signal.

6. The optical transmitter of claim 1, wherein the amplifier is to amplify the power of the optical data signal by at least 4 decibels (dB).

7. An electronic device comprising:
an active element to produce a data signal; and
an optical transmitter to produce an output signal with a power of at least 5 decibels with reference to one milliwatt (dBm), wherein the optical transmitter includes:
a substrate;
a laser coupled with the substrate, wherein the laser is to produce an optical signal with a power between 10 and 40 milliwatts (mW);
a modulator coupled with the substrate, wherein an input of the modulator is communicatively coupled with an output of the laser, and wherein the modulator is to encode the data signal into the optical signal to produce an optical data signal with a power less than the power of the optical signal; and
a semiconductor optical amplifier (SOA) coupled with the substrate, wherein an input of the SOA is communicatively coupled with an output of the modulator, and wherein the SOA is to amplify the power of the optical data signal to produce the output signal, and wherein the SOA includes a III-V material.

8. The electronic device of claim 7, wherein the SOA has a curved profile.

9. The electronic device of claim 7, wherein the SOA has a tapered profile.

10. The electronic device of claim 7, wherein the optical transmitter further includes an optical coupler that is to couple with an optical fiber, wherein the optical coupler is to receive the output signal.

11. The electronic device of claim 7, wherein the SOA is to directly couple with, and provide the output signal to, an optical fiber.

12. The electronic device of claim 7, wherein the optical transmitter further includes a multiplexer that is to receive the output signal.

13. An optical transmitter comprising:
a first optical signal path that includes:
a first laser to produce a first optical signal with a power of less than 40 milliwatts (mW); and
a first amplifier to produce a first output signal with a power of at least 5 decibels with reference to one milliwatt (dBm), wherein the first output signal is based on the first optical signal;
a second optical signal path that includes:
a second laser to produce a second optical signal with a power of less than 40 mW; and
a second amplifier to produce a second output signal with a power of at least 5 dBm, wherein the second output signal is based on the second optical signal; and
a multiplexer to combine the first output signal and the second output signal to produce a multiplexed output signal.

14. The optical transmitter of claim 13, further comprising a third amplifier to increase a power of the multiplexed output signal.

15. The optical transmitter of claim 14, further comprising an optical coupler communicatively positioned between the multiplexer and the third amplifier.

16. The optical transmitter of claim 14, further comprising an optical coupler communicatively coupled with an output of the third amplifier.

17. The optical transmitter of claim 14, wherein the third amplifier has a tapered profile as viewed in a direction perpendicular to a face of a substrate to which the first laser is coupled.

18. The optical transmitter of claim 14, wherein the third amplifier has a curved profile as viewed in a direction perpendicular to a face of a substrate to which the first laser is coupled.

19. The optical transmitter of claim 13, wherein the multiplexer is physically coupled to a same substrate as the first laser and the second laser.

20. The optical transmitter of claim 13, wherein the multiplexer is physically separate from a substrate to which the first laser is coupled.
